(19) United States
(12) Patent Application Publication
(10) Pub. No.: US 2020/0152354 A1
(43) Pub. Date: May 14, 2020

(54) INTEGRATED CIRCUITS IN CABLE

(71) Applicant: Minnesota Wire, St. Paul, MN (US)

(72) Inventors: Paul J. Wagner, Eagan, MN (US); Eric J. Wagner, Mendota Heights, MN (US); Chris Howells, St. Paul, MN (US); Matt Market, St. Paul, MN (US); Kevin Voigt, St. Paul, MN (US)

(73) Assignee: Minnesota Wire, St. Paul, MN (US)

(21) Appl. No.: 16/684,447

(22) Filed: Nov. 14, 2019

Related U.S. Application Data
(60) Provisional application No. 62/767,437, filed on Nov. 14, 2018.

(51) Int. Cl. H01B 7/04; H01B 11/10; H01B 13/26; H01B 3/18; H05K 9/00

(52) U.S. Cl. CPC H01B 7/04; H01B 11/1025; H05K 9/0098; H01B 3/18; H01B 13/26

(57) ABSTRACT

Systems and methods presented herein provide for elastomeric and flexible cables. In one embodiment, the cables are configured with elastomeric cabling and circuitry. For example, a flexible circuit line (or lines) may be wrapped about an extruded elastomeric substrate (e.g., a polymer). Integrated circuits (e.g., sensors, accelerometers, light emitting diodes, controllers, microprocessors, etc.) may be disposed at various points along the circuit line(s). The cable may then be wrapped with a Polytetrafluoroethylene (PTFE) tape than can be heated to shrink about the cable for protection of the underlying circuitry. Then, the cable may be surrounded with a layer of polymer and extruded to form an elastomeric and flexible cable.

### CROSS REFERENCE TO RELATED APPLICATIONS

This patent application claims priority to, and thus the benefit of an earlier filing date from, U.S. Provisional Patent Application No. 62/767,437 (filed Nov. 14, 2018), the contents of which are hereby incorporated by reference.

### BACKGROUND

Wire and cable are ubiquitous. They exist in buildings, vehicles, electronic devices, appliances, utilities, agriculture, construction, wearable electronics, etc. Problems may occur when wires and cables are continuously flexed because the metal in the wire eventually fractures and reduces its conductivity.

### SUMMARY

Systems and methods presented herein provide for elastomeric and/or flexible cables. In one embodiment, the cables are configured with conductive cabling and circuitry. For example, a flexible circuit line (or lines) may be wrapped about an extruded elastomeric substrate (e.g., a polymer). Integrated circuits (e.g., sensors, accelerometers, light emitting diodes—“LEDs”, controllers, thermistors, microprocessors, etc.) may be disposed at various points along the circuit line(s). The cable may then be wrapped with a Polytetrafluoroethylene (PTFE) tape that can be heated to shrink about the cable for protection of the underlying circuitry. Other types of wraps that may be used include Lycra, textiles (e.g., cotton), aramids such as Kevlar, etc. Then, the cable may be surrounded with a jacket and extruded to form an elastomeric and/or flexible cable. The end of the cable may also be terminated such that a communication and/or power can be applied to the cable to stimulate the underlying circuitry.

The embodiments herein may find a variety advantageous uses. For example, the stretchable cables with circuitry may be used in clothing to sense a variety of parameters on the user (e.g., body motion, temperature, etc.). In other embodiments, the cables may be used to measure glacial motions and/or volcanic movement that stretch the cable.

### BRIEF DESCRIPTION OF THE DRAWINGS

FIG. 1 is a perspective view of an exemplary elastomeric cable.

FIG. 2 is a perspective view of an exemplary flexible cable with a plurality of integrated circuits.

FIG. 3 is a perspective view of another exemplary flexible cable with a plurality of integrated circuits.

FIG. 4 is a perspective view of another exemplary flexible cable with a plurality of integrated circuits.

FIGS. 5A and 5B illustrate an exemplary cable configured with an optically transparent extruded component.

FIG. 6 is a perspective view of an exemplary flexible cable configured with a stacked configuration of integrated circuits and circuit lines.

### DETAILED DESCRIPTION OF THE DRAWINGS

The figures and the following description illustrate specific exemplary embodiments. It will thus be appreciated that those skilled in the art will be able to devise various arrangements that, although not explicitly described or shown herein, embody the various principles and are included within the scope of the claims. Furthermore, any examples described herein are intended to aid in understanding the principles of the embodiments and are to be construed as being without limitation to such specifically recited examples and conditions. As a result, the embodiments herein are not limited to the specific examples described below.

The various embodiments illustrate elastomeric and/or flexible cables and their various constructions. For example, the cables disclosed may include an elastomeric non-conductive core or substrate configured from a polymer. This may allow the cable to stretch and bend more easily while cabling components, such as flexible circuitry configured with one or more integrated circuits, provide the desired cable functionality (e.g., power, data, etc.).

In some embodiments, a jacket may be wrapped or extruded about the cable to provide protection for the underlying circuitry. For example, a jacket may be configured about a length of the cable and extruded to provide the overall cable.

The cable may include a “stay cord” for the cable. For example, a stay cord may be wound about a length of the cable such that the cable can stretch due to the elasticity of the elastomeric core. But, based on the winding of the stay cord, the overall cable will only be able to stretch so far because the cabling component compresses against the core as the cable is stretched. This compression tends to stiffen the elastomeric core and aids in preventing the cable from breaking and/or protecting the electrical integrity of the components. In some embodiments, the stay cord may be a long lay (e.g., running along a length of the cable) or spiral lay. A long lay stay cord may allow the cable to stretch a certain length (e.g., the length of the stay cord), whereas a spiral lay stay cord may cause the stay cord to compress against the core to prevent over stretching.

Some embodiments are now described, by way of example only, and with reference to the accompanying drawings. The same reference number represents the same element or the same type of element on all drawings. For example, an elastomeric cable 100 disclosed herein may comprise circuitry, optical fibers, conductors, shieldings, protective covers, etc. Thus, the elastomeric cable 100 as disclosed herein comprises an elastomeric core with various configurations of cabling components.

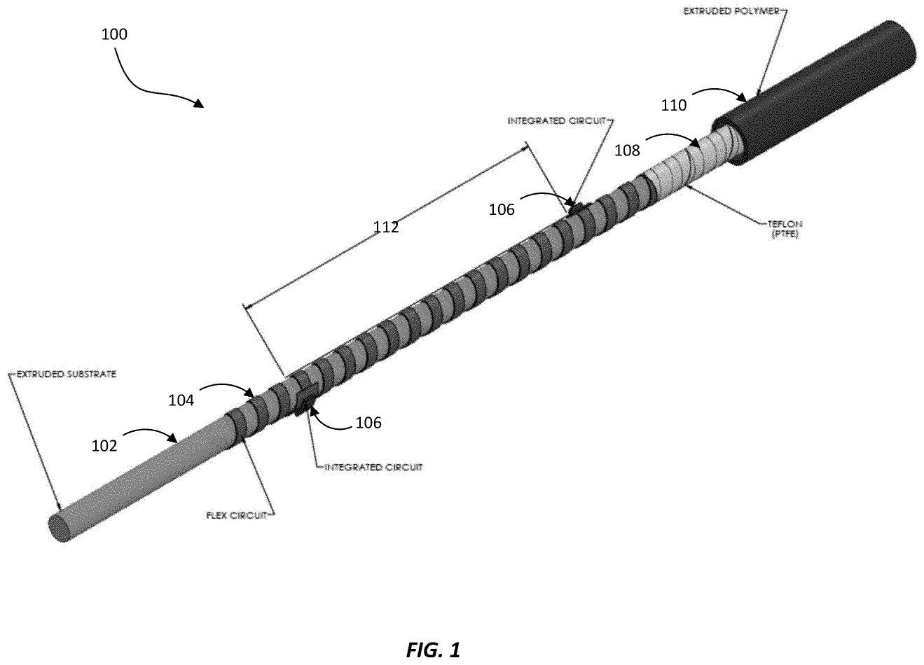

Turning now the illustrated embodiments, FIG. 1 is a perspective view of an exemplary elastomeric cable 100. In this embodiment, the cable has an extruded substrate 102 configured from an elastomeric material, such as a polymer, rubber, etc. This allows the cable 100 to stretch and bend more easily than traditional cables. The extruded substrate 102 has a flexible circuitry 104 disposed about the substrate 102 along a length of the cable 100. For example, the flexible circuitry 104 may comprise one or more circuit lines embedded in a flexible material that provides insulation and flexibility to the circuit lines. The flexible circuitry 104 may be spirally wrapped about the substrate 102 along the length of the cable 100 and terminated at ends of the cable 100, as shown and described in greater detail below.

Configured with the flexible circuitry 104 is one or more integrated circuits 106. For example, integrated circuits 106 may be disposed at various locations (e.g., separated by some distance 112) along the length of the cable 100. These integrated circuits 106 may be electrically coupled to the circuit lines of the flexible circuitry 104. The integrated circuits 106 may provide various forms of functionality to the cable 100, such as sensing (e.g., temperature, altitude, motion, etc.), communicating, processing, etc. In this regard, the integrated circuits 106 may comprise sensors, accelerometers, light emitting diodes—“LEDs”, controllers, thermistors, microprocessors, micromechanical systems (MEMS), micromechanical mirrors, or the like. In some embodiments, the integrated circuits may be two sided.

The cable 100 may then be wrapped with a PTFE tape 108 (or other material) to cover and/or protect the underlying circuitry (i.e., flexible circuitry 104 and integrated circuits 106). In some embodiments, the cable 100 may be configured with an extruded jacket 110 (e.g., polymer) along a length of cable 100.

The cable 100 comprises a flexibility due to the “stretchy” nature of the elastomeric substrate 102 and the flexible circuitry 104. This flexibility may allow the cable 100 to be fitted or otherwise configured with fabric to be worn by a user to provide various forms of functionality to the user. For example, in one embodiment, the integrated circuits 106 may comprise accelerometers that are used to detect various motion parameters of the user (e.g., heart rate, blood pressure, etc.). The cable 100 can be woven into or otherwise sewn to clothing that the user wears. A power supply (not shown) may be configured with the clothing or otherwise worn by the user to supply power to a terminated end of the flexible circuitry 104 and thus to the integrated circuits 106 of the cable 100. Then, the accelerometers would detect the motion parameters of the user and communicate such information to the user (e.g., wirelessly, by coupling to a computer, by coupling to a device worn by the user, etc.).

In some embodiments, the substrate 102 comprises a plurality of Lycra/spandex legs (e.g., a configured as a bungee cord, each comprising a gauge as small as 6/C AWG 40. A jacked may be configured about the cable with an outer diameter in this embodiment being about 0.053″. Thus, the embodiment may be advantageously used in the garment and wearable marketplace. However, other embodiments (e.g., for the pipeline industry where extreme strength is needed) the substrate 102 may comprise strands of about 0.150″ with a jacket having an outer diameter of about 0.240″. Such an embodiment may comprise a cable break strength of about 600 pounds or more (e.g., using braided aramid to achieve the strength). In some embodiments, a material is spirally served with the circuit line(s) and the integrated circuit(s) to provide elasticity thereto. However, the embodiments are not intended to be limited to any particular dimensions and/or break strength.

In some embodiments, elasticity is achieved based on a ratio of the conductor diameter to the core diameter, generally about 40% for the wearable electronics industry. One thing that may negatively impact stretch is shielding. Thus, in some embodiments, shielding may be wrapped around individual conductors and circuit lines prior to being wrapped around the elastic core. Alternatively or additionally, a served shielding in the opposite direction (e.g., right hand lay/left hand lay) may be implemented over all the conductors. In some embodiments, a double shield and/or metal foil may be used for dB shielding improvement. In such an embodiment, a high strand material in a left hand lay and another layer in a right hand lay may be spirally wrapped about the cable.

In some embodiments, a single pass extrusion process, multiple rubber cores are created, cut, bundled together, and braided bungee style. A textile may be braided about this resulting elastomeric core. Then, electrical and/or optical conductors (extruded and/or jacketed) may be spirally wrapped about the elastomeric core.

In some embodiments, the flexible circuitry 104 may comprise copper, silver, and/or or gold traces that are laminated with a polyimide or similar materials. Then, the flexible circuitry 104 and/or the integrated circuits 106 may be die cut and terminated. In some embodiments, a stretchable polyurethane may be applied to a low durometer side to protect the integrity of the flexible circuitry 104 and/or the integrated circuits 106. Of course, braids, such as nylon, cotton, and/or aramids may be used to protect the integrity of the flexible circuitry 104 and/or the integrated circuits 106. In some embodiments, an outer jacket (e.g., PTFE, plumbing tape, or the like) is spiral wrapped on the flexible circuitry 104 and/or the integrated circuits 106. Alternatively or additionally, a material may be sintered about the flexible circuitry 104 and/or the integrated circuits 106 via an inline baking process.

In some embodiments, the flexible circuitry 104 and the one or more integrated circuits 106 is encompassed with a material. For example, a liquid plastic may surround the flexible circuitry 104 and the one or more integrated circuits 106 and then hardened. Alternatively, the flexible circuitry 104 and the one or more integrated circuits 106 may be encompassed with an elastomeric material that may be extruded with the flexible circuitry 104 and the one or more integrated circuits 106 to form a cable. Alternatively or additionally, the cables herein may be encased in a heat shrink to form a jacket to protect the underlying circuit lines and circuitry.

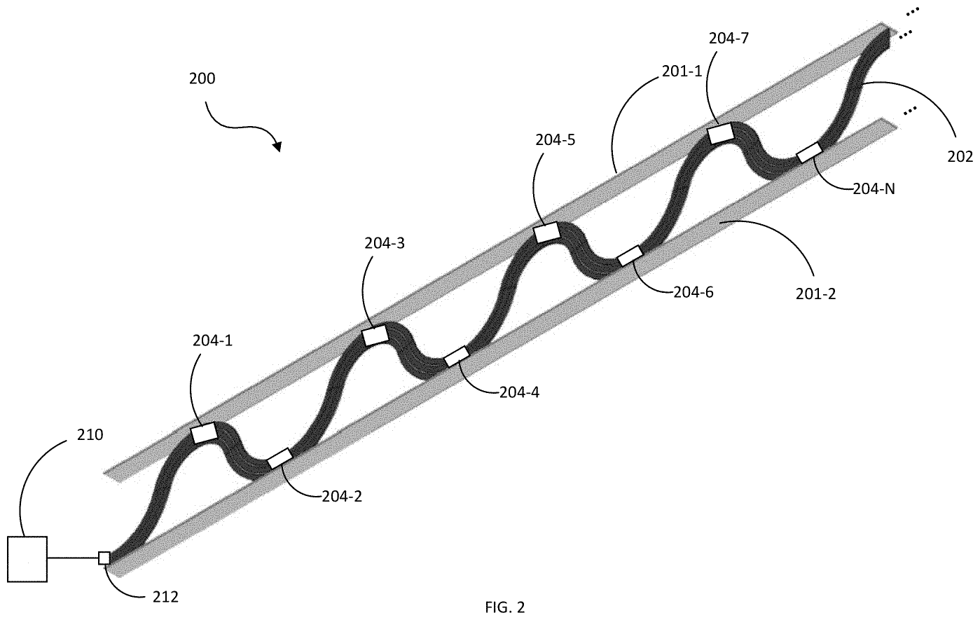

FIG. 2 is a perspective view of an exemplary flexible cable 200 configured with a plurality of integrated circuits 204-1-204-N (where “N” represents an integer greater than “1” and not necessarily equal to any other “N” reference designated herein). In this embodiment, the flexible cable 200 is configured with strips 201-1 and 201-2 of flexible material. A plurality of circuit lines 202 are disposed between the strips 201. And, configured with the circuit lines 202 are a plurality of integrated circuits 204-1-204-N. For example, the integrated circuits 204, in one embodiment, may include sensors such as accelerometers that are operable to detect motion.

In such an embodiment, the cable 200 could be employed in clothing to detect motion of a user wearing the clothing. For example, the cable 200 may be employed in the sole of a shoe. The circuit lines 202, being disposed between the strips 201-1 and 201-2 in a serpentine configuration, may allow the cable 200 to flex or “squish” without breaking the circuit lines 202 when a user wears the shoe. Thus, when the user is walking, the integrated circuits 204 may detect various features of the user's gait.

To illustrate, a user with mobility issues (e.g., a person who is injured, an elderly person, etc.) may on occasion have a tendency to fall. A portion of the integrated circuits 204 may detect the user's gait. The cable 200 may include a terminated coupling 212 that is coupled to a processor 210 that is operable to determine when the user is about to fall based on the user's detected gait. The processor 210 may then stimulate another portion of the integrated circuits 204 to correct the user's gait. For example, a portion of the integrated circuits 204 may include vibrotactile stimulators. The processor 210, upon detecting that the user is about to fall, directs one or more of the integrated circuits 204 to vibrate along a portion of the user's foot to correct the user's gait. In this regard, the cable 200 may be operable to train a user to walk correctly, such as when the user has incurred a brain injury.

The cable 200 as illustrated herein is not intended to be limited to just footwear. The cable 200 may be implemented in a variety of ways as a matter of design choice. For example, the cable 200 may be integrated into clothing to sense various other attributes of a user such as motion, breathing, body temperature, blood pressure, etc. Accordingly, the integrated circuits 204 may include any of a variety of sensors and/or other electronics. Additionally, the cable 200 may be used in industrial applications to, for example, determine vibration of various machines. The cable 200 may also be implemented with temperature sensors that can be used in various refrigeration processes. For example, the cable 200 may be implemented in a refrigerated transport that may experience various mechanical stresses. The cable 200 may flex under these mechanical stresses without breaking thereby providing more reliable temperature evaluation within the transport.

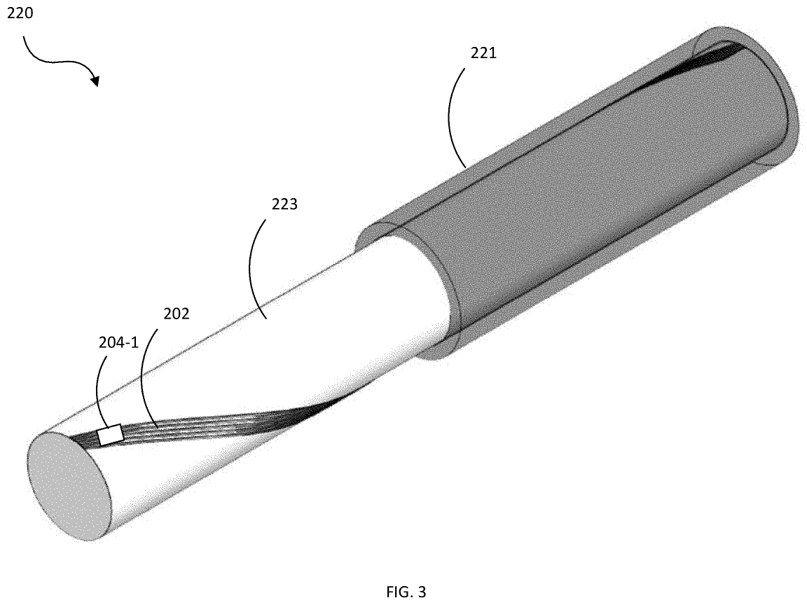

FIG. 3 is a perspective view of an exemplary flexible cable 220 with a plurality of integrated circuits 204 disposed along a plurality of circuit lines 202. In this embodiment, the circuit lines 202 are laid along a flexible and/or elastomeric core 223 which may then be surrounded by a flexible jacket 221. This embodiment may provide advantageous uses in the medical industry. For example, the integrated circuits 204 may include sensors that monitor a patient. Due to the elastomeric and flexible nature of the cable 220, the cable 220 may provide the patient with more comfort.

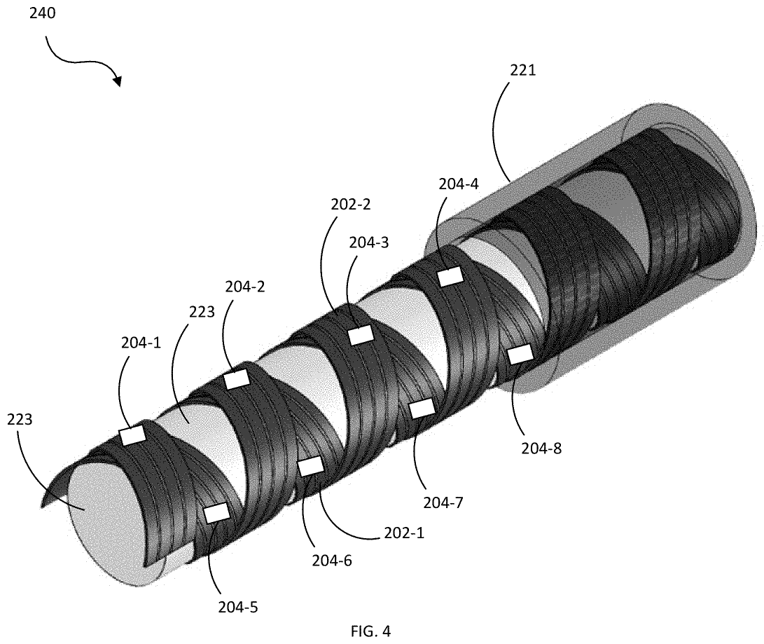

FIG. 4 is a perspective view of an exemplary flexible cable 240 with a plurality of integrated circuits 204 disposed along a plurality of circuit lines 202. In this embodiment, the cable 240 has one set of circuit lines 202-1 with integrated circuits 204-5, 204-6, 204-7, and 204-8 wrapped about a flexible and/or elastomeric core 223. A second set of circuit lines 202-2 is configured with a plurality of integrated circuits 204-1, 204-2, 204-3, and 204-4 wrapped about the circuit lines 202-1. The cable 240 may then be covered with a jacket 221. In this embodiment, the core 223 allows the cable to be stretched to some degree and/or flexed. As the circuit lines 202-2 are laid in an opposite fashion of the circuit lines 202-1, the circuit lines 202-2 slide across the circuit lines 202-1 when the cable 240 is flexed.

In some embodiments, the circuit lines 202-1 and 202-2 are operable to act as a sort of stay cord that prevents the cable from breaking when stretched. For example, as the cable 240 is stretched along its length, the circuit lines 202-1 and 202-2 may function as a sort of “finger trap” that compresses against the core 223 and prevents the cable 240 from being stretched too far.

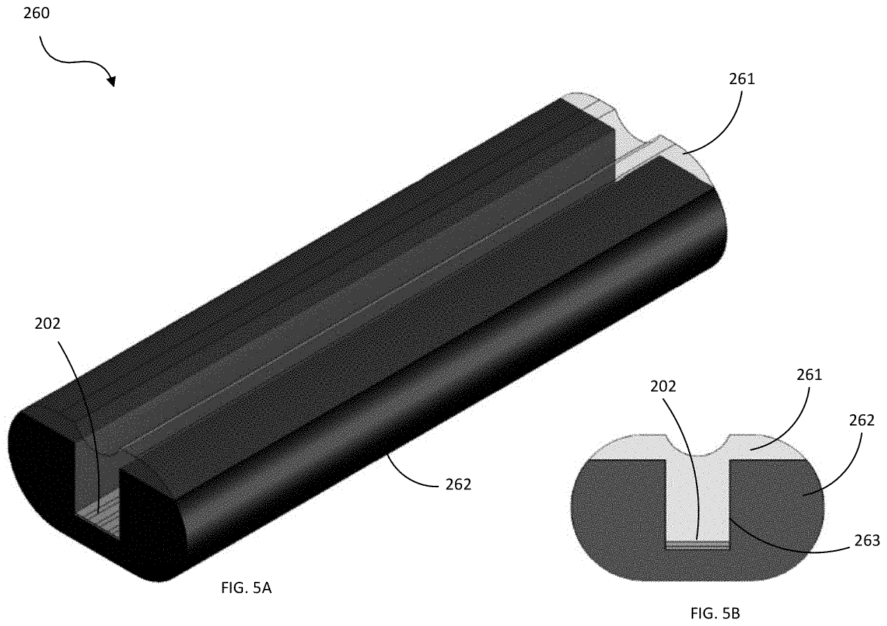

FIGS. 5A and 5B illustrate an exemplary cable 260 configured with an optically transparent extruded component 261. In this embodiment, the cable 260 includes an extruded base component 262. The base component 262 is extruded with a notch 263 such that a plurality of circuit lines 202 may be laid therein. From there, the base component 262 may be configured with an optically transparent component 261. In this regard, the circuit lines 202 may include a variety of optical sensors and optical transmitters (e.g., light emitting diodes) that may be used for a variety of purposes.

For example, the cable 260 may be implemented in a band like configuration which is secured about a user's forehead. The optical sensors and transmitters of the circuit lines 202 may be pulse oximeters that are used to monitor the user's blood pressure, oxygen level, heart rate, etc. As with the above embodiments, the cable 260 may be terminated with a connector that communicatively couples to a processing system that can provide the user with real-time data. For example, the cable 260 may be implemented in a scuba mask for military applications. In this regard, the processing system may provide real-time data pertaining to the user's biometrics via a heads up display in the scuba mask when the user descends underwater so that the user is aware of his or her human limits.

In some embodiments, the optically transparent component 261 may configured in a variety of ways as a matter of design choice to assist in optical propagation. For example, the optically transparent component 261 as shown is configured with a concave shape 264 that may operate as a concave lens. In other embodiments, the optically transparent component 261 may include a convex shape or even a flat shape.

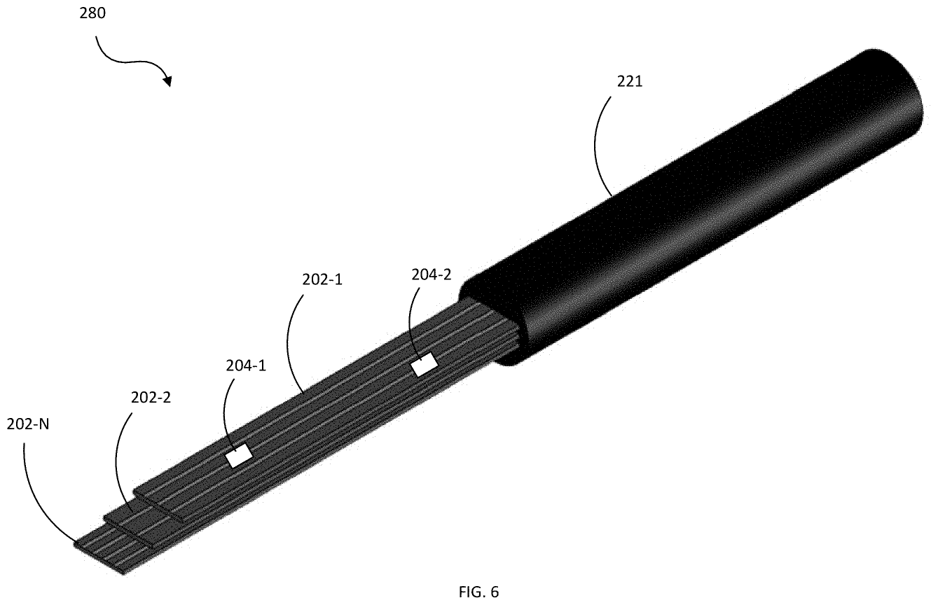

FIG. 6 is a perspective view of an exemplary flexible cable 280 configured with a stacked configuration of circuits lines 202-1, 202-2, . . . 202-N each of which is configured with one or more integrated circuits 204. The cable 280 may then be configured (e.g., extruded) with a jacket 221 that is operable to protect the circuit lines 202. This configuration may provide certain advantages in manufacturing. For example, the cable 280 may be rapidly terminated with a connector that allows each of the circuit line sets to quickly couple to a processing system.

Any of the cores shown and described herein of the various cables may be implemented in a variety of ways as a matter of design choice. For example, the cores may be implemented via polyurethane, braided Kevlar and/or nylon, Lycra. Additionally, any of the cables shown and described herein may be processed in a variety ways as a matter of design choice. For example, the cables may be implemented with the extruded cores, extruded primaries that are wrapped in sintered, jacketed with Kevlar, polyvinyl chloride (PVC), Ethylene tetrafluoroethylene (ETFE), Fluorinated ethylene propylene (FEP), polyurethane (PU), and the like. In some embodiments, particularly for cables used in wearable electronics, the cables and their terminations may include washing machine protection such that the clothing may be washed without damaging the underlying integrated circuitry. Additionally, the embodiments herein are not limited to any number of circuit lines and/or any number and type of integrated circuits.

Although shown and described with each of the cables comprising a plurality of integrated circuits disposed with the circuit lines, some embodiments may not include the integrated circuits. For example, some of the processing capabilities may be offloaded onto the termination connection. In other embodiments, the cables may be configured to mate between processing capabilities.

The embodiments shown and described herein may be combined and/or rearranged in a variety of ways as a matter of design choice that still fall within the scope of protection being sought.

What is claimed is:

1. A cable, comprising:
a plurality of integrated circuits disposed along a plurality of circuit lines;
at least one termination electrically coupled to the circuit lines and operable to communicatively couple to a processor; and
a flexible jacket surrounding at least a portion of the flexible circuit.

2. The cable of claim 1, further comprising:
an extruded elastomeric core, wherein the plurality of integrated circuits is wrapped about the elastomeric core and are operable to restrain the elastomeric core when stretched.

3. The cable of claim 2, further comprising another plurality of integrated circuits disposed along another plurality of circuit lines, wherein the other plurality of integrated circuits the other plurality of circuit lines are wrapped about the plurality of integrated circuits and the plurality of circuit lines in an opposite lay, wherein the other plurality of integrated circuits and the other plurality of circuit lines are operable to slide across the plurality of integrated circuits and the plurality of circuit lines based on the opposite lay when the cable is flexed.

4. The cable of claim 1, wherein:
the flexible jacket comprises a notch;
the plurality of integrated circuits comprises at least one optical transmitter and at least one optical sensor;
and the circuit lines, the at least one optical transmitter, and the at least one optical sensor are disposed within the notch; and
the cable further includes an optically transparent material configured within the notch atop the integrated circuits and the circuit lines.
